(19) United States
(12) Patent Application Publication
(10) Pub. No.: US 2005/0169033 A1
(43) Pub. Date: Aug. 4, 2005

(54) Semiconductor module

(75) Inventors: Norihiko Sugita, Kodaira (JP); Takafumi Kikuchi, Higashiyamato (JP); Koichi Miyashita, Hino (JP); Hikaru Ikegami, Koganei (JP)

Correspondence Address: REED SMITH LLP, 3110 FAIRVIEW PARK DRIVE, SUITE 1400, FALLS CHURCH, VA, 22042, US

(73) Assignee: Hitachi, Ltd.

(21) Appl. No.: 11/095,571

(22) Filed: Apr. 1, 2005

Related U.S. Application Data
(63) Continuation of application No. 10/070,256, filed on Mar. 4, 2002.

(51) Int. Cl. G11C 5/06

(52) U.S. Cl. 365/63

(57) ABSTRACT

A high speed operating circuit such as a data processor chip and memory chips constituting an electronic circuit is mounted to a multilayer wiring substrate in the state of a bare chip, and is set to a multichip module. This multichip module is mounted to a wiring substrate constituting the electronic circuit. In the multichip module, buffer circuits are inserted into a module internal bus commonly connected to the data processor chip and the memory chips. The buffer circuits are set to an address output buffer, a control signal output buffer and a data input/output buffer set to a high impedance state in accordance with an operating selection of the memory chips. When high frequency noise resisting characteristics are strengthened by the multilayer wiring substrate and the data processor chip gets access to the memory chips, an external noise tends to flow into a memory through the module internal bus connected to the data processor chip and the memory chips. However, the buffer circuits restrain the flow-in of such an external noise and prevent memory data from being broken by the high frequency noise during a memory access operation.

### BACKGROUND OF THE INVENTION

1. Field of the Invention

The present invention relates to a semiconductor module mounting plural semiconductor integrated circuit chips thereto, and relates to an effective technique applied to a multichip module in which a data processor chip and a memory chip are mounted to e.g., a multilayer wiring substrate.

2. Background Art

An electronic circuit for performing image processing, etc. is constructed by a data processor called a microprocessor or a microcomputer, etc., and a high speed operating memory represented by a synchronous DRAM (hereinafter called SDRAM), etc. accessed by the data processor in many cases. A high speed operation such as a 100 MHz operation and a 133 MHz operation represented by standards of “PC100”, “PC133”, etc. is further required in the recent SDRAM. When the high speed operation must be performed by including the high speed operating memory of this kind, etc. in the electronic circuit, it is also important to take a high frequency noise measure in accordance with the high speed operation. There is a case in which a print substrate (which is a printed circuit board and is hereinafter called PCB) mounting the SDRAM and the data processor often becomes an unneglectable high frequency noise source. Therefore, for example, it is considered with respect to the print substrate that the high frequency impedance of a power line is reduced and the print substrate is surrounded by a shield frame and equivalent electrostatic capacity of the print substrate is increased by devising the power line, and a multilayer wiring structure is adopted.

However, it is difficult to form the print substrate of predetermined desirable performance and manufacture cost of the print substrate is extremely increased when the entire print substrate is set to the multilayer wiring structure.

In addition, the present inventors have clarified that there is further room for consideration with respect to the high frequency noise measure of a circuit portion operated at high speed and a technique for mounting plural kinds of LSIs such as microprocessors to the multilayer wiring substrate.

Firstly, it is necessary to sufficiently prevent memory data from being broken by a high frequency noise during the high speed operation of a memory. One considered technique is a technique for arranging a high speed operating circuit such as a microprocessor, an I/O port and a random access memory in the multilayer wiring substrate, and mounting this multilayer wiring substrate to the print substrate such as a mother board. In this technique, it is possible to expect some degree of a preferable operation of the high speed operating circuit by the multilayer wiring substrate. However, in this construction, when a noise due to a high frequency wave flows-in through a bus connected to the memory and the microprocessor, read data or write data of the memory during an access operation are undesirably changed on the bus.

Secondly, it is necessary to consider the mounting layout of a device and the functional allocation of an external connecting electrode. Namely, it is desirable to reduce the influence of an external noise flowing-in through a module internal bus, etc. connected to the memory and the microprocessor on the read data or the write data of the memory during the access operation. Therefore, it is desirable to consider the mounting layout of the devices of several kinds to a module substrate and also consider the functional allocation of the external connecting electrode of the module substrate.

Thirdly, it is necessary to reduce a process number for mounting and assembling the devices into the multilayer wiring substrate so as not to reduce yield and reliability of the semiconductor module when the mounting layout of the devices of several kinds to the module substrate is determined.

An object of the present invention is to provide a semiconductor module able to prevent memory data from being broken by a high frequency noise during a memory access operation, and an electronic circuit in which this semiconductor module is mounted to a mother board.

Another object of the present invention is to provide a semiconductor module and an electronic circuit in which a high speed operating circuit of a data processor chip, a memory chip, etc. is arranged in a multilayer wiring substrate, and no external noise is easily flowed into a memory through a module internal bus connected to these chips when this multilayer wiring substrate is mounted to a print substrate such as a mother board and the data processor chip gets access to the memory chip.

Still another object of the present invention is to provide a semiconductor module in which read data or write data of the memory during the access operation are not easily undesirably changed on the module internal bus.

Another object of the present invention is to provide a semiconductor module able to relax the influence of an external noise in view of the mounting layout of several kinds of semiconductor integrated circuit chips to a module substrate.

Another object of the present invention is to provide a semiconductor module able to relax the influence of the external noise in view of the functional allocation of an external connecting electrode of the module substrate mounting several kinds of semiconductor integrated circuit chips thereto.

Another object of the present invention is to provide a semiconductor module able to contribute to the improvement of yield and reliability by reducing a process number for mounting and assembling several kinds of semiconductor integrated circuit chips into the module substrate.

Still another object of the present invention is to provide a semiconductor module such as a multichip module in which the semiconductor module can perform a high speed operation by restraining a high frequency noise and has high external noise resisting performance and high reliability, and the high speed operation, and the high external noise resisting performance and the high reliability can be realized at relatively low cost.

The above and other objects and novel features of the present invention will become apparent from the following description of this specification and the accompanying drawings.

The present inventors have found the following publicly known examples after the present invention was completed.

One example is Japanese Patent Laid-Open No. 220498/1989. This publication discloses an invention in which a high frequency noise is easily emitted from a bus line for connecting a microprocessor and an I/O port and a sufficient noise reducing effect is obtained by arranging at least a portion of this bus line on a multilayer substrate while a large increase in cost is prevented. It is also described that a large part of a portion most easily generating the high frequency noise is mounted onto the multilayer substrate if a random access memory is also mounted to this multilayer substrate.

Another example is Japanese Patent Laid-Open No. 335364/1993. This publication describes an invention with respect to a multilayer wiring substrate in which a mounting area of a memory LSI is arranged around a bare-mounting area of a microprocessor LSI.

However, in these publicly known examples, there is no description about the above room for further consideration.

### SUMMARY OF THE INVENTION

<<Buffer for Strengthening Noise Resisting Performance>>

In a semiconductor module in a first viewpoint of the present invention, a data processor chip, a memory chip and a buffer circuit able to be considered as a switch circuit are arranged in a module substrate having plural external connecting electrodes and plural wiring layers connectable to the plural external connecting electrodes. The data processor chip and the memory chip are commonly connected to a module internal bus formed by the wiring layers. The buffer circuit is inserted into the module internal bus, and interrupts an input from the external connecting electrode connected to the module internal bus in access of the memory chip using the data process chip.

In accordance with the above construction, it is possible to prevent memory data from be broken by a high frequency noise during a memory access operation.

For example, the buffer circuit is an address output buffer for outputting an address signal toward the external connecting electrode, a control signal output buffer for outputting an access control signal toward the external connecting electrode, and a data input/output buffer set to a high impedance state in accordance with an operating selection of the memory chip. Since the address output buffer and the control signal output buffer restrain a signal input at any time, there is no flow-in of the noise through these output buffers. Direction control of ordinary data in the data input/output buffer is set to an input in a reading operation of the data processor and an output in a writing operation of the data processor. However, in the present invention, it is controlled to the high impedance state in response to the operating selection of the memory chip. Accordingly, when the data processor chip gets access to the memory chip, no external noise easily flows into a memory through the module internal bus connected to the data processor chip and the memory chip. Accordingly, it is possible to restrain the memory data from being broken by the high frequency noise during the memory access operation.

The buffer circuit may be also set to an address input/output buffer, a control signal input/output buffer and a data input/output buffer. In this case, these input/output buffers are set to the high impedance state in accordance with the operating selection of the memory chip. Since the input/output buffers are controlled to the high impedance state in response to the operating selection of the memory chip, no external noise easily flows into a memory through the module internal bus connected to the data processor chip and the memory chip when the data processor chip gets access to the memory chip. Accordingly, it is possible to restrain the memory data from being broken by the high frequency noise during the memory access operation.

In view of the restriction of the high frequency noise, the module substrate is preferably set to a multilayer wiring structure in which the equivalent electrostatic capacity between a signal pattern and a power pattern or a ground pattern is increased and can be uniformed over the entire circuit by a structure for setting a power wiring pattern and a ground wiring pattern to solid patterns uniformly formed as conductive layers on the entire surface. At this time, it is possible to preferably prevent the module substrate from being warped if a structure constructed by a base layer having plural wiring layers and a buildup layer formed by overlapping wiring layers respectively having the same layer number on front and rear faces of the base layer is adopted as this multilayer wiring structure.

Even when high frequency noise resisting characteristics are strengthened by the multilayer wiring substrate, the external noise begins to flow into the memory through the module internal bus connected to the data processor chip and the memory chip when the data processor chip gets access to the memory chip. However, the buffer circuit restrains such flow-in of the external noise and prevents the memory data from being broken by the high frequency noise during the memory access operation.

<<Noise Resisting Performance Strengthening Layout>>

In a multichip module in a second viewpoint of the present invention, many external connecting electrodes connected to wiring layers are arranged on one face of a module substrate having the plural wiring layers, and a mounting pad connected to the wiring layers and mounting plural semiconductor integrated circuit chips is arranged on the other face of the module substrate. The mounting pad is separated into an area of the mounting pad of the plural semiconductor integrated circuit chips able to be operated at relatively high speed, and an area of the mounting pad of the plural semiconductor integrated circuit chips operated at relatively low speed.

If the high and low speed operating areas are separated from each other on the module substrate, the function of the external connecting electrode arranged on the rear face of the module substrate can be determined in accordance with the difference in circuit characteristics between the high and low speed operating areas.

For example, the external connecting electrode allocated to an address and data is arranged on the rear face of the area for mounting the plural semiconductor integrated circuit chips operated at relatively low speed. Since the input and output operations of an address and data in the operation of the multichip module are frequently performed at high speed, it is possible to relax that the circuit of the high speed operating area is influenced by a noise generated in such a frequent portion of a signal change.

Further, relatively many external connecting electrodes allocated to supply a power voltage and a ground voltage can be arranged on the rear face of the area for mounting the plural semiconductor integrated circuit chips operated at relatively high speed. If the number of external connecting terminals for power supply is relatively increased, the number of external connecting electrodes allocated for signal input and output is relatively reduced. Accordingly, it is possible to relax that the circuit of the high speed operating area is influenced by the external noise.

In a multichip module in another viewpoint of the external noise flow-in relaxation layout, many external connecting electrodes connected to wiring layers are arranged on one face of a module substrate having the plural wiring layers, and a data processor chip, memory chips and buffer circuits connected to the wiring layers are arranged on the other face of the module substrate. The data processor chip is arranged approximately at the center of the module substrate, and the plural memory chips are arranged on one side and the plural buffer circuits are arranged on the other side in parallel with each other with respect to the data processor chip. In accordance with this construction, the data processor chip and the memory chips are operated at relatively high speed or frequently, and the buffer circuits are operated at comparatively low speed or their operating frequencies are comparatively low in comparison with these chips. In accordance with this layout, similar to the above case, the high and low operating areas are separated from each other.

In a multichip module in still another viewpoint of the external noise flow-in relaxation layout, many external connecting electrodes connected to wiring layers are arranged on one face of a module substrate having the plural wiring layers, and a data processor chip, a memory chip and a buffer circuit are arranged on the other face of the module substrate through a mounting pad connected to the wiring layers. The external connecting electrodes corresponding to the input-output of an address and data are arranged on the rear face of an area for mounting the buffer circuit. Thus, a frequent external connecting electrode portion of a signal change as in the input-output of an address and data can be separated from a high speed operating portion such as the data processor chip and the memory chip.

In a multichip module in still another viewpoint of the external noise flow-in relaxation layout, many external connecting electrodes connected to wiring layers are arranged on one face of a module substrate having the plural wiring layers, and a data processor chip, a memory chip and a buffer circuit are arranged on the other face of the module substrate through a mounting pad connected to the wiring layers. Relatively many external connecting electrodes allocated to supply a power voltage and a ground voltage are arranged on the rear face of an area for mounting the memory chip. Thus, similar to the above case, a frequent external connecting electrode portion of a signal change as in an address output and data input-output can be separated from a high speed operating portion such as the data processor chip and the memory chip.

In a multichip module in still another viewpoint of the external noise flow-in relaxation layout, many external connecting electrodes connected to wiring layers are arranged on one face of a module substrate having the plural wiring layers, and plural kinds of semiconductor integrated circuit chips are arranged on the other face of the module substrate through a mounting pad connected to the wiring layers. The external connecting electrodes for operating power allocated to supply the power voltage and the ground voltage are coarsely or closely arranged on the module substrate, and the external connecting electrodes allocated for the operating power are closely arranged on the rear face of the semiconductor integrated circuit chip having larger power consumption. In charging and discharging operations of an internal circuit in the semiconductor integrated circuit chip, there is a correlation in which the power consumption is generally increased as the charging and discharging operations are frequently performed at high speed. Accordingly, if this viewpoint is noticed and the external connecting electrodes allocated for the operating power are closely arranged on the rear face of the semiconductor integrated circuit chip having larger power consumption, a frequent external connecting electrode portion of a signal change as in an address output and a data input-output is relatively separated from a high speed operating portion in comparison with a low speed operating portion.

<<Reduction in Assembly Process Number>>

In a semiconductor module in view of a reduction in assembly process number, plural external connecting electrodes are arranged on one face of a module substrate, and a mounting pattern is formed on the other face of the module substrate. The mounting pattern has a grouped pattern able to arrange semiconductor integrated circuit chips approximately having an equal height size in one line and mount these chips every group of the semiconductor integrated circuit chips. The mounting pattern and a bump electrode of the semiconductor integrated circuit chip are electroconductively connected to each other through an anisotropic electroconductive film stuck every grouped pattern. Since the mounting pattern able to stick the anisotropic electroconductive film every group of the semiconductor integrated circuit chips approximately having the equal height size is adopted, one anisotropic electroconductive film is stuck every this group and the plural semiconductor integrated circuit chips can be collectively crimped to the anisotropic electroconductive film and can be heated every this group. In this respect, the number of processes for mounting and assembling several kinds of semiconductor integrated circuit chips into the module substrate can be reduced. Thus, it is possible to contribute to the improvement of yield and reliability of the semiconductor module. Cost of the multichip module can be also reduced.

<<Address Delay Reduction Wiring>>

In a semiconductor module in which the viewpoint of arranging address input timing to a memory chip is noticed, many external connecting electrodes connected to wiring layers are arranged on one face of a module substrate having the wiring layers, and a data processor chip and plural memory chips connected to the wiring layers are mounted to the other face of the module substrate. The memory chips respectively have electrode pads arranged in one line, and plural memory chips are arranged in a direction crossing an arranging direction of the electrode pads. The wiring layers for supplying an address to the respective memory chips are extended in the arranging direction of the memory chips, and are sequentially connected to the electrode pads for the address input.

<<Mother Board and Daughter Board>>

In an electronic circuit of the present invention in which the relation of a mother board and a daughter board mounted onto this mother board is noticed, a first semiconductor device and a second semiconductor device able to be operated at high speed in comparison with the first semiconductor device are mounted to a bus of a wiring substrate in a common connecting state. The relation of the second semiconductor device with respect to the wiring substrate corresponds to the relation of the daughter board with respect to the mother board. In the second semiconductor device, a data processor chip and a memory chip commonly connected to the bus through an external connecting electrode are arranged in a multilayer wiring substrate, and a buffer circuit is arranged in a wiring path from the data processor chip and the memory chip to the external connecting electrode. The buffer circuit interrupts an input from the bus in access of the memory chip using the data processor chip.

An address output buffer, a control signal output buffer and a data input/output buffer respectively inserted into the wiring path may be adopted as the buffer circuit. The data input/output buffer may be controlled to a high impedance state in response to an access command of the memory chip given by the data processor chip. The buffer circuit may be also set to an address input/output buffer, a control signal input/output buffer and a data input/output buffer respectively set to the high impedance state in accordance with an operating selection of the memory chip.

The external connecting electrode corresponding to the address output and the data input-output may be arranged on the rear face of an area for mounting the buffer circuit.

Relatively many external connecting electrodes allocated to supply a power voltage and a ground voltage may be arranged on the rear face of an area for mounting the memory chip.

In accordance with the above construction, the second semiconductor device such as a multichip module can relax a high frequency noise and can be operated at high speed, and has high external noise resisting performance and high reliability as the entire electronic circuit, and these contents can be realized at comparatively low cost.

### BRIEF DESCRIPTION OF THE DRAWINGS

FIG. 1 is an external appearance view showing one example of an electronic circuit in the present invention using a multichip module;

FIG. 2 is an external appearance view of an electronic circuit in a comparison example adopting no multichip module;

FIG. 3 is a plan view showing one example of a chip layout of the multichip module;

FIG. 4 is a bottom view of the multichip module shown in FIG. 3;

FIG. 5 is an explanatory view illustrating a function allocating state with respect to an external connecting electrode of the multichip module;

FIG. 6 is a block diagram of the multichip module;

FIG. 7 is an explanatory view showing one example of a connecting mode of a data processor chip and a memory chip in terminal correspondence;

FIG. 8 is a block diagram showing one example of the data processor chip;

FIG. 9 is a logic circuit diagram of an output buffer;

FIG. 10 is a block diagram of an input/output buffer and a logic gate chip;

FIG. 11 is a plan view illustrating the arrangement of an address signal line with respect to a bonding pad of the memory chip of a center pad;

FIG. 12 is an explanatory view showing a connecting state of the memory chip and the signal line of an address bus in the entire multichip module 3;

FIG. 13 is a sectional view showing one example of a multilayer wiring structure in a multilayer wiring substrate;

FIG. 14 is an explanatory view showing some main portions in a process for mounting a bare chip to a module substrate in a flip chip system;

FIG. 15 is a sectional view illustrating a sectional structure of a joining portion of a bump electrode and a mounting pad;

FIG. 16 is an explanatory view of the multichip module showing a state in which plural bare chips are mounted by sticking an anisotropic electroconductive film every group of the bare chip;

FIG. 17 is another functional block diagram of the multichip module;

FIG. 18 is a logic circuit diagram illustrating a data input/output buffer of FIG. 17 and one portion of a logic gate chip for controlling an operation of this data input/output buffer;

FIG. 19 is a logic circuit diagram illustrating an address input/output buffer and a control signal input/output buffer of FIG. 17 and one portion of a logic gate chip for controlling operations of these buffers;

FIG. 20 is a detailed explanatory view of FIG. 13 showing the connection relation of a gold bump electrode such as a ground terminal or a power terminal, etc. arranged in a semiconductor integrated circuit chip, and each external connecting electrode formed in the multilayer wiring substrate;

FIG. 21 is a detailed explanatory view of FIG. 13 showing the connection relation of the gold bump electrode as a signal terminal arranged in the semiconductor integrated circuit chip, and each external connecting electrode formed in the multilayer wiring substrate; and

FIG. 22 is a sectional view showing one example of the wiring substrate as a print substrate.

### DESCRIPTION OF THE PREFERRED EMBODIMENTS

<<Mother Board and Multichip Module>>

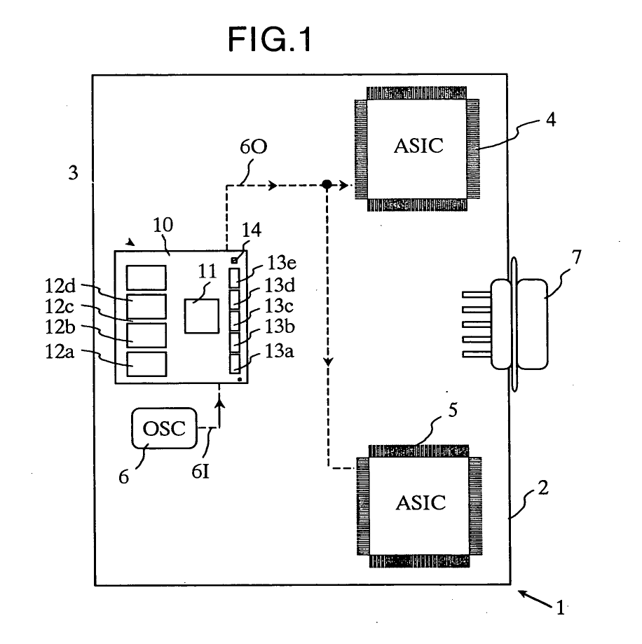

FIG. 1 shows one example of an electronic circuit in the present invention using a multichip module. The electronic circuit 1 shown in this figure is not particularly limited, but is a circuit in which a circuit portion requiring high speed data processing such as image processing and a circuit portion requiring no very high speed operation for realizing a communication function and a monitoring function of a system are mixed and mounted as in a digital copying machine, a car navigation device, etc.

In the electronic circuit 1 shown in FIG. 1, a multichip module 3 as a semiconductor module, ASICs (Application Specified ICs: ICs for a specific use) 4, 5 and a crystal oscillator (OSC) 6 are mounted to a wiring pattern in which the illustration of a wiring substrate 2 is omitted. An input/output connector 7 is connected to the predetermined wiring pattern omitting the illustration of the wiring substrate 2 so that the electronic circuit 1 can be connected to another device. The connector 7 is not limited to an illustrated mode, but can be variously changed. For example, the wiring substrate 2 is a print substrate of low cost in which a wiring pattern of about two layers is printed on each of the front and rear sides of glass epoxy resin.

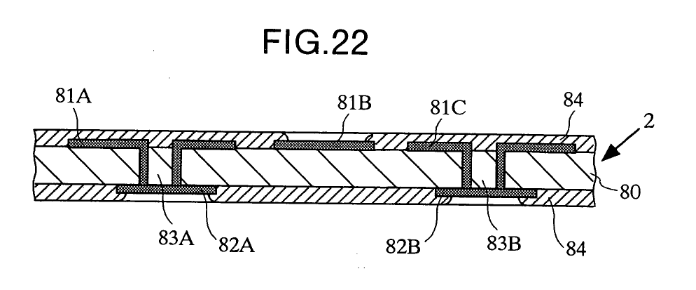

FIG. 22 illustrates one portion of the wiring substrate 2 as the print substrate in longitudinal section. Copper wirings 81A, 81B and 81C are formed on the front face of a glass epoxy resin substrate 80. Copper wirings 82A, 82B are formed on a rear face of the glass epoxy resin substrate 80. The copper wirings are covered and protected by a solder resist layer 84 except for a portion utilized in a connecting portion for mounting the multichip module 3 and the ASICs 4, 5, etc. In the illustrated example, the copper wiring 81A is connected to the copper wiring 82A through a through hole 83A, and the copper wiring 81C is connected to the copper wiring 82C through a through hole 83B, and a wiring situation using two wiring layers on the front and rear faces is schematically shown. However, this example is one example schematically showing the wiring structure. Various wiring patterns are actually formed in accordance with predetermined desirable wirings.

In the electronic circuit 1, the high frequency impedance of a power line may be raised by a bypass capacitor and the electronic circuit 1 may be surrounded by a shield frame as a general high frequency noise measure although this structure is not particularly illustrated.

In the multichip module 3, a data processor chip 11 as a bare chip, memory chips 12a to 12d, buffer chips 13a to 13e and a logic gate chip 14 are respectively mounted to a multilayer wiring substrate 10 on which many external connecting electrodes are arranged on a bottom face. The multichip module 3 is set to one example of a second semiconductor device operated at comparatively high speed. When the relation of a mother board set to a first mounting substrate and a daughter board as a second mounting substrate mounted onto this mother board is noticed, a first semiconductor device and the second semiconductor device operable at high speed in comparison with the first semiconductor device are mounted to a bus of the wiring substrate 2 in a common connecting state. The relation of the multichip module 3 with respect to the wiring substrate 2 corresponds to the relation of the daughter board with respect to the mother board.

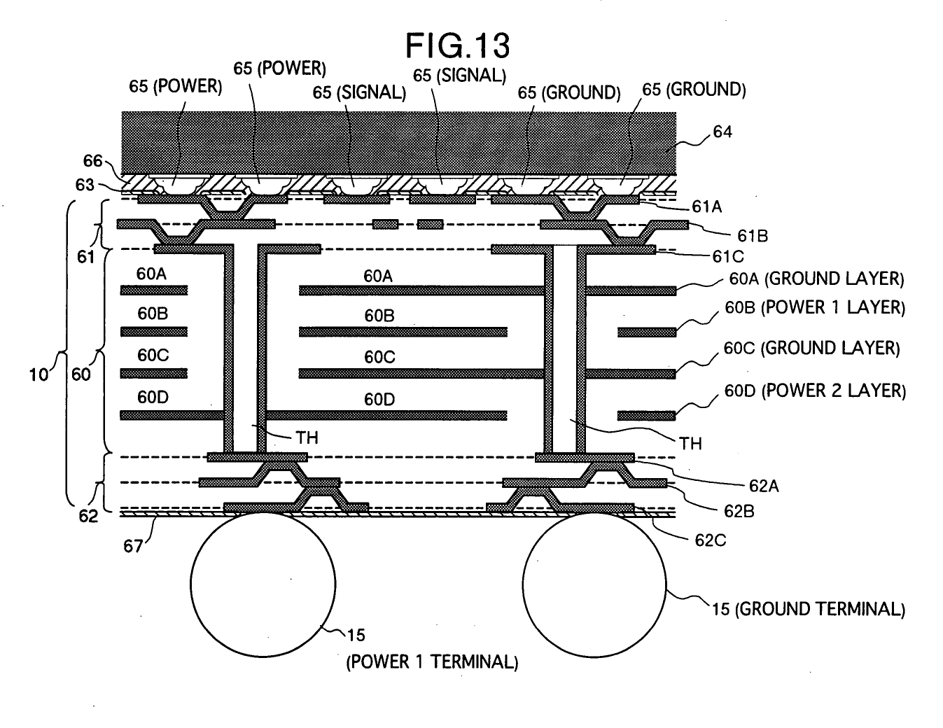

The multilayer wiring substrate 10 has a wiring pattern of plural layers as described later by using FIGS. 13, 20 and 21. For example, the equivalent electrostatic capacity between a signal pattern and a power pattern or a ground pattern can be increased and uniformed over the entire circuit by a structure in which a power wiring pattern and a ground wiring pattern are uniformly set to solid patterns of conductive layers on the entire surface, etc. This multilayer wiring structure itself can show a function for restraining generation and diffusion of the high frequency noise to a certain extent. A wiring layer arranged in this multilayer wiring substrate 10 is connected to the external connecting electrode on one face of this multilayer wiring substrate 10, and is connected to a mounting pad of the bare chip on the other face. The multilayer wiring substrate 10 will be described later in detail.

The ASICs 4, 5 are located as a peripheral circuit of the data processor chip 11, and are set to a circuit having a peripheral function such as communication and monitoring, etc., and are also set to one example of the first semiconductor device having an operating speed lower than that of the second semiconductor device. For example, the ASICs 4, 5 are semiconductor chips stored to a flat package.

The crystal oscillator 6 supplies a clock signal as an operating reference to the multichip module 3 and the ASICs 4, 5. In accordance with FIG. 1, the reference clock outputted from the oscillator 6 is inputted to the substrate 10 through a wiring 6I of the substrate 2. The reference clock inputted to the substrate 10 is supplied to the processor chip 11 through a wiring within the substrate 10 and is set to a predetermined desirable frequency, e.g., 200 MHz by a clock pulse generating circuit within the data processor chip 11, and is also set to an operating clock of the data processor chip 11. On the other hand, the data processor chip 11 outputs operating clocks of the memory chips 12a to 12d and operating clocks of the ASICs 4, 5. The operating clocks for the ASICs 4, 5 are supplied from the substrate 10 to the ASICs 4, 5 through a wiring 60 within the substrate 2. The multichip module 3 and the ASICs 4, 5 receive instructions and data inputted via the input/output connector 7 and start processing. The multichip module 1 and the ASICs 4, 5 input and output data through an unillustrated common bus during this processing. Final processing results using the multichip module 1 and the ASICs 4, 5 are outputted from the input/output connector 7 to the exterior.

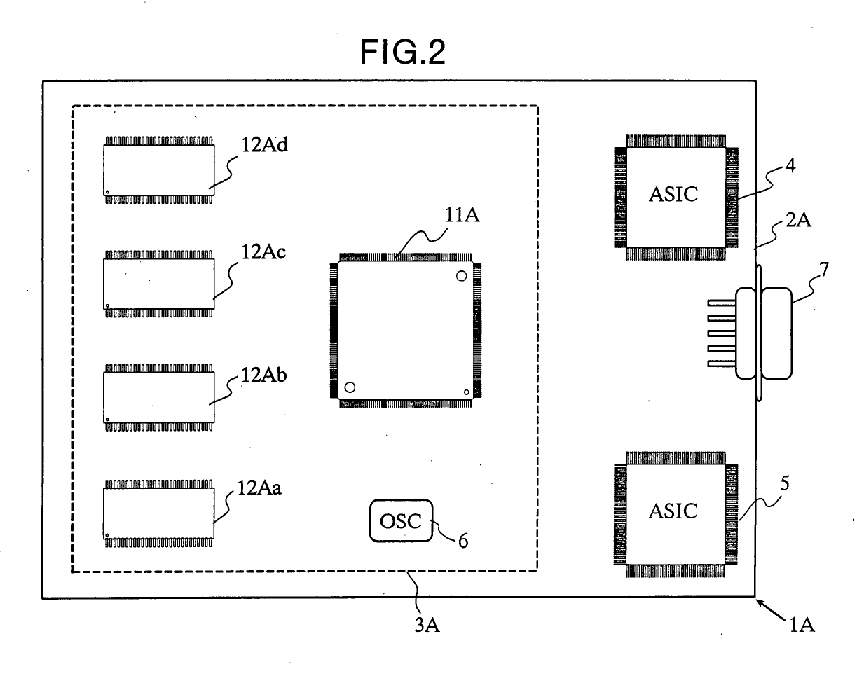

FIG. 2 shows the external appearance of an electronic circuit in a comparison example adopting no multichip module 3. The function of the multichip module 3 is replaced by plural semiconductor integrated circuit chips included in an area 3A surrounded by a broken line of FIG. 2. Namely, in the electronic circuit 1A of FIG. 2, a data processor 11A and memories 12Aa to 12Ad are mounted to a wiring substrate 2A as the semiconductor integrated circuit individually packaged instead of the multichip module 3 of FIG. 1. The data processor 11A and the memories 12Aa to 12Ad operated at relatively high speed and the ASICs 4, 5 able to be operated at comparatively low speed are commonly connected to the same bus on the wiring substrate 2A. No circuits corresponding to the buffer chips 13a to 13e of FIG. 1 are arranged.

When a device to be operated at high speed and a device able to be operated at low speed are connected to the common bus as shown in FIG. 2, a high speed operation is required in at least a wiring connected between the data processor 11A and the memories 12Aa to 12Ad in design of the wiring substrate 2A having this common bus. Therefore, it is difficult to satisfy electric characteristics and external noise resisting performance. If the entire wiring substrate 2A is set to a multilayer wiring structure, this requirement is satisfied but cost is greatly increased. At this time, as shown in FIG. 1, if a circuit portion requiring the high speed operation is constructed by the multichip module 3, no remaining circuits such as the ASICs 4, 5. require the high speed operation. Therefore, a design burden for the high frequency noise measure in the wiring substrate 2 can be greatly reduced.

As mentioned above, a chip part mounted to the multilayer wiring substrate 10 of FIG. 1 is here set to a bare chip unsealed in an IC package. Accordingly, in comparison with parts packaged here, an occupying area is reduced so that a delay component such as a resistance component and a capacity component parasitic on the wirings within the circuits is reduced and suitable for the high speed operation. Further, since a large amount of the wirings is completed within the multichip module 3, the number of wirings left in the wiring substrate 2 is reduced so that the number of wiring layers of the wiring substrate 2 can be reduced. This contributes to a reduction in manufacture cost of the wiring substrate 2. Further, as mentioned above, the area of the wiring substrate 2 itself can be reduced by using the multichip module 3 in which plural bare chips are mounted and sealed in one multilayer wiring substrate 10. Since the multichip module 3 has a size approximately equal to an outer shape of the packaged data processor 11A, the wiring substrate 2 itself can be also reduced and it is suitable for an assembly use into a compact device such as a portable terminal. For example, the size of the module 3 can be reduced to 27 mm×27 mm.

With respect to changes caused by the improvement of a product and the development of a product kind, the wiring substrate 2 of the electronic circuit can be commonly utilized by making a plan from the beginning such that only the mounted multichip module is corrected. Accordingly, manufacture cost of the entire electronic circuit 1 can be also reduced. Namely, when the construction of the electronic circuit 1 or 1A is intentionally changed, the entire wiring substrate 2A is redesigned in the case of FIG. 2. However, in the case of FIG. 1, the redesign of the wiring substrate 2 can be set to be unnecessary by setting a changing point within the multichip module 3.

<<Noise Resisting Performance Strengthening Layout>>

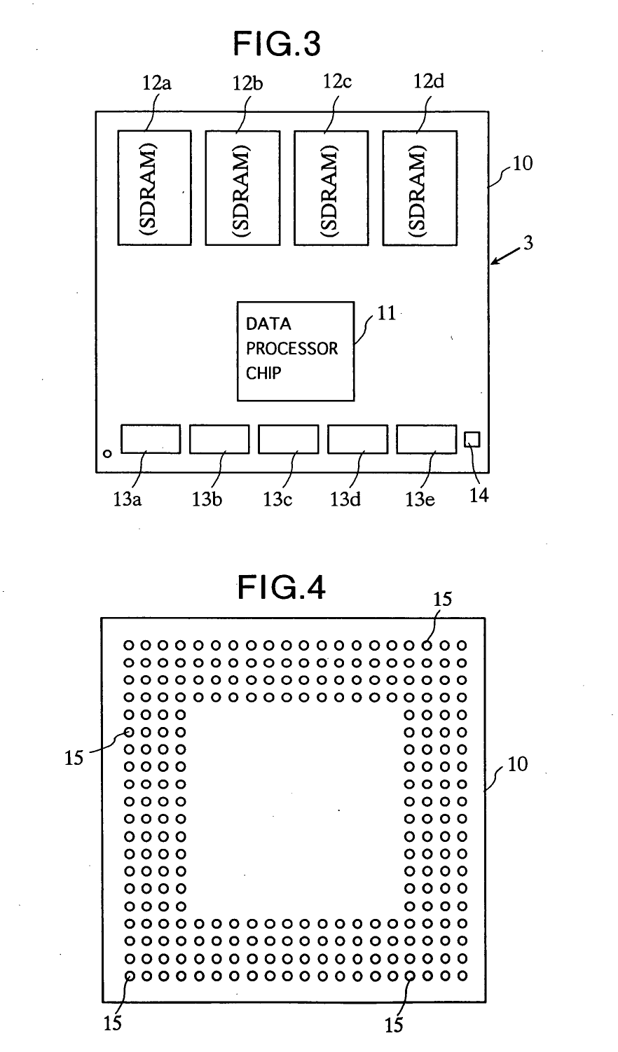

FIG. 3 shows one example of the chip layout of the multichip module. In FIG. 3, a data processor chip 11 and memory chips 12a to 12d operated at comparatively high speed and buffer chips 13a to 13e and a logic gate chip 14 operated at comparatively low speed are separated and arranged in the multilayer wiring substrate 10. In particular, the data processor chip 11 is arranged approximately at the center of the multilayer wiring substrate 10, and the plural memory chips 12a to 12d are arranged on one side and the plural buffer chips 13a to 13e and the logic gate chip 14 are arranged on the other side in parallel with each other through the data processor chip 11. Passive parts such as a bypass capacitor and a resistor for oscillation prevention may be naturally mounted onto the module substrate in accordance with necessity although illustration of these passive parts is omitted in FIG. 3.

FIG. 4 shows a bottom face of the multichip module shown in FIG. 3. Many external connecting electrodes 15 are arranged on the bottom face of the multilayer wiring substrate 10 so as to surround the bottom face in four lines. The external connecting electrodes 15 are not particularly limited, but are respectively constructed by a solder ball. Each external connecting electrode 15 is set to have a diameter of 0.76 mm, and the distance between the centers of the respective external connecting electrodes 15 is set to 1.27 mm although this diameter and this distance are not particularly limited. The multilayer wiring substrate 10 adopted here is not particularly limited, but an outer shape similar to that of the IC package of a form called a ball grid array (hereinafter called BGA) is adopted. For example, the multilayer wiring substrate 10 is set in conformity with the BGA package of 256 pins. Another package form may be also naturally used in the multichip module 3.

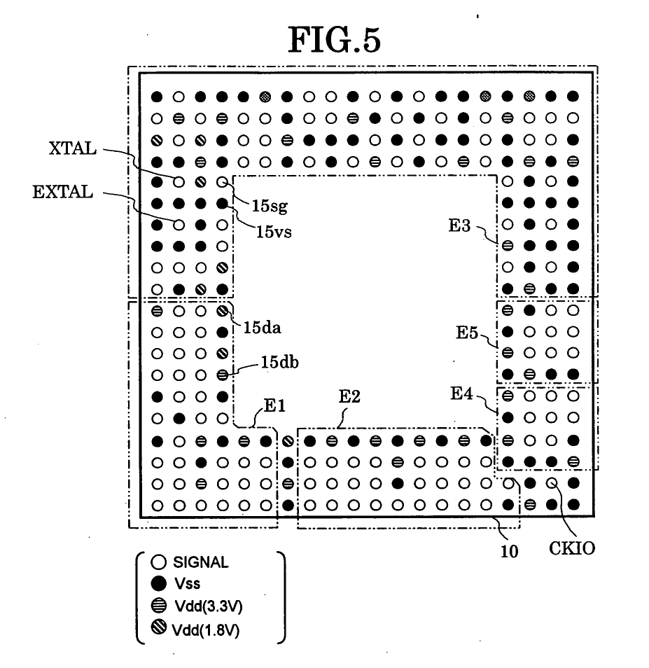

FIG. 5 illustrates a function allocating state with respect to the external connecting electrode of the multichip module. An orientation of FIG. 5 is conformed to that of FIG. 3.

Memory chips 12a to 12d are generally arranged on the rear face of an area E5 in FIG. 5. Buffer chips 13a to 13e and a logic gate chip 14 are generally arranged on the rear faces of areas E1 to E4.

In FIG. 5, an external connecting electrode 15vs of a black circle is set to a supply terminal (ground terminal) of a ground voltage Vss of a circuit. External connecting electrodes 15da, 15db of a slanting line circle and a parallel line circle are set to supply terminals of power voltages Vdd of 1.8 V and 3.3 V, and an external connecting electrode 15sg of a white circle is set to a signal terminal. Power of 1.8 V is set to operating power of a CPU of the data processor chip. The other circuits are set to 3.3 V in operating power in principle.

The external connecting electrode 15sg of the areas E1, E2 is allocated to a data input-output and an address output as a signal frequently changed or often varied. In contrast to this, the external connecting electrode 15sg of the area E3 is allocated to the input and the output of a hand shake signal of the data processor chip such as an interruption signal and a data transfer request signal as a signal gently changed or varied a little. The number of electrodes 15da, 15db, 15vs particularly allocated to the supply of a power voltage Vdd and a ground voltage Vss is relatively increased in this area E3. The external connecting electrode 15sg of the area E4 is allocated to the output of a chip select signal, etc., and the external connecting electrode 15sg of the area E5 is allocated to the outputs of a write signal, a read signal, etc. Some of the external connecting electrodes 15sg for a signal are generally surrounded by the external connecting electrodes 15da, 15db, 15vs for power. This is because a noise measure of the signal is taken. Reference numeral CKIO designates a clock output terminal to ASICs 4, 5, and reference numerals XTAL, EXTAL designate connecting terminals to the oscillator 6.

In FIG. 5, almost all of the external connecting electrodes in one line circulated in an innermost circumference are allocated to the supply of the power voltage and the ground voltage to strengthen the power supply to the data processor chip 11 mounted to a central portion of the multilayer wiring substrate 10.

The data processor chip 11 and the memory chips 12a to 12d are operated at comparatively high speed or frequently. In comparison with the data processor chip 11 and the memory chips 12a to 12d, the buffer chips 13a to 13e and the logic gate chip 14 are operated at comparatively low speed or their operating frequencies are comparatively small. If the memory chips 12a to 12d, the buffer chips 13a to 13e and the logic gate chip 14 are laid out on both sides of the data processor chip 11 as shown in FIG. 3, a high speed operating area and a low speed operating area are separated from each other. If the high and low speed operating areas are separated from each other on the module substrate 10, the function of the external connecting electrode arranged on the rear face of the multilayer wiring substrate 10 can be determined in accordance with the difference in circuit characteristics between the high and low speed operating areas.

For example, the external connecting electrode corresponding to the address output and the data input-output is arranged on rear faces E1, E2 in an area for mounting the buffer chips 13a to 13e and the logic gate chip 14 operated at relatively low speed. Since address output and data input/output operations are frequently performed at high speed in the operation of the multichip module, it is possible to relax that the data processor chip 11 and the memory chips 12a to 12d as a circuit in the high speed operating area are influenced by a noise generated in a frequent portion of such a signal change. Thus, noise resisting performance can be strengthened.

The number of external connecting electrodes 15da, 15db, 15vs allocated to the supply of the power voltage Vdd and the ground voltage Vss is relatively increased in a rear face area E3 in an area for mounting the data processor chip 11 and the memory chips 12a to 12d operated at relatively high speed. The number of external connecting electrodes 15sg allocated to the signal input/output is correspondingly relatively reduced in this area E3. This means that an external connecting electrode portion having a frequent signal change as in the address output and the data input/output is separated from a high speed operating portion such as the data processor chip and the memory chips. Accordingly, it is possible to relax that the data processor chip 11 and the memory chips 12a to 12d operated at high speed are influenced by an external noise. In this respect, the noise resisting performance is also strengthened.

The above viewpoint of the strengthening of the noise resisting performance can be gripped as density with respect to an arrangement of the external connecting electrode for operating power allocated to the supply of the power voltage and the ground voltage. The external connecting electrodes allocated for the operating power are closely arranged on the rear face of a semiconductor integrated circuit chip having larger power consumption. In charging and discharging operations of an internal circuit in the semiconductor integrated circuit chips 11, 12a to 12d, 13a to 13e, 14, there is generally a correlation in which power consumption is increased as the charging and discharging operations are frequently performed at high speed. Accordingly, if this viewpoint is noticed, the external connecting electrode portion having a frequent signal change as in the address output and the data input/output is relatively separated from the high speed operating portion in comparison with a low speed operating portion if the external connecting electrodes allocated for the operating power are closely arranged on the rear face of the semiconductor integrated circuit chip having larger power consumption.

<<Buffer for Strengthening Noise Resisting Performance>>

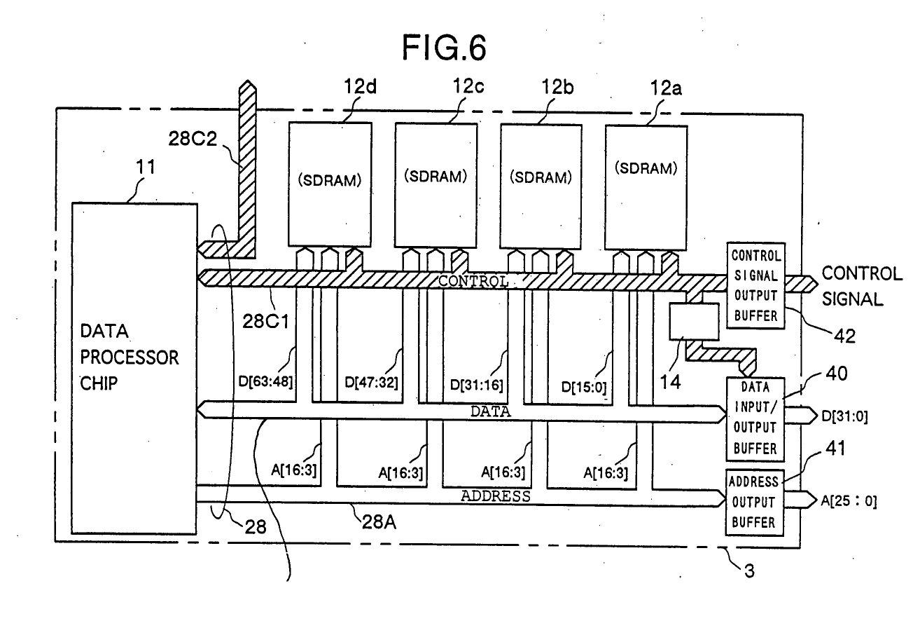

FIG. 6 illustrates a functional block diagram of the multichip module.

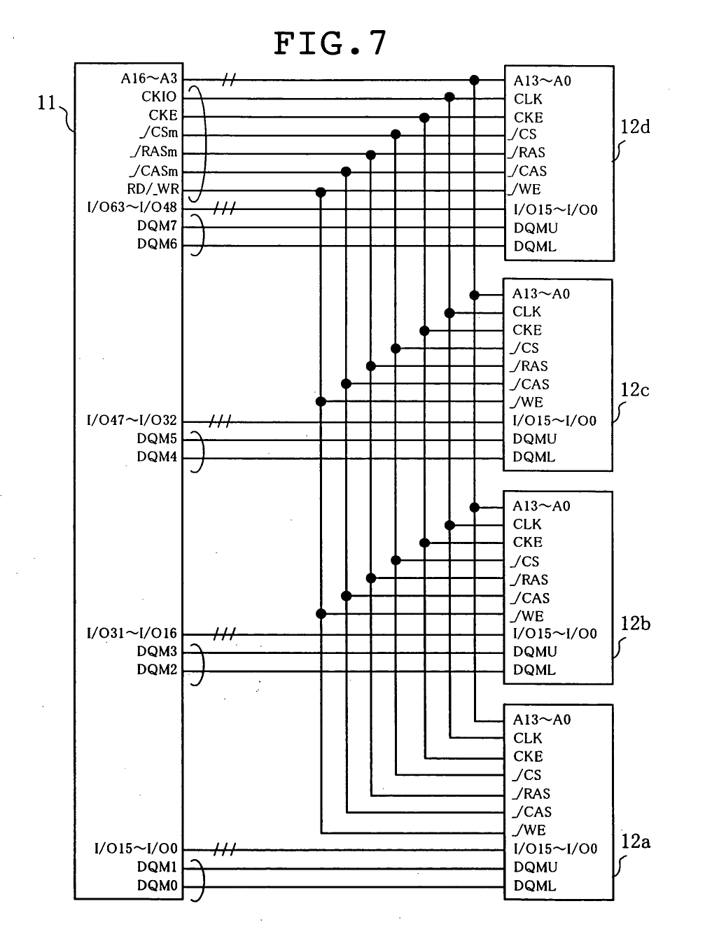

FIG. 7 shows one example of a connecting mode of the data processor chip and the memory chips in terminal correspondence.

For example, each of the memory chips 12a to 12d is constructed by an SDRAM, and functions as a main memory of the data processor chip 11.

The SDAM has the matrix of a dynamic type memory cell in a memory cell array although this matrix is not particularly shown in FIGS. 6 and 7. Low active, column active reading, column active writing, refreshing operations, etc. are commanded by a command signal supplied in synchronization with a clock signal. The reading and writing operations are performed in synchronization with the clock signal by using an address signal supplied together with the commands, or an address signal generated in an internal address counter. If a burst operation is commanded, data of a predetermined burst number can be continuously read or written. As illustrated in FIG. 7, the SDRAMs 12a to 12d have ICS (chip selection), /RAS (low address strobe), /CAS (column address strobe), /WE (write enable), CLKE (clock enable), CLK (clock) and DQML, DQMH (data mask) as input terminals of an access control signal in addition to address input terminals A13 to A0 and data input/output terminals I/O15 to I/O0. DQML and DQMH (data mask) are control terminals for masking input data in a byte unit in a burst writing operation.

In FIG. 6, the multichip module 3 has a data bus 28D, an address bus 28A and control buses 28C1, 28C2 as a module internal bus 28.

An address signal line A[16:3] of 14 bits included in the address bus 28A is commonly connected to the memory chips 12a to 12d. The memory chips 12a to 12d and a signal line of the data bus 28D are individually connected in a unit of 16 bits. A signal line D[15:0] of 16 bits is connected to the memory chip 12a. A signal line D[31:16] of 16 bits is connected to the memory chip 12b. A signal line D[47:32] of 16 bits is connected to the memory chip 12c. A signal line D[63:48] of 16 bits is connected to the memory chip 12d. The control bus 28C1 is a general term of a signal line group connected to the memory chips 12a to 12d. For example, an individual signal every memory chip is supplied to the terminals DQML, DQMH (data mask), and a common signal is supplied to the other terminals /CS (chip selection), /RAS (low address strobe), /CAS (column address strobe), /WE (write enable), etc. in each memory chip. The control bus 28C2 is a bus for a control signal, e.g., an interruption signal, a DMA request signal, a DMA acknowledge signal, etc. not connected to the memory chips.

FIG. 7 shows address output terminals A16 to A3, data input/output terminals I/O63 to I/O0 and access control terminals CKIO, CKE, /CSm, /RASm, /CASm, RD/WR, DQM7 to DQM0 as corresponding terminals of the data processor chip 11 connected to the above terminals of the memory chips 12a to 12d.

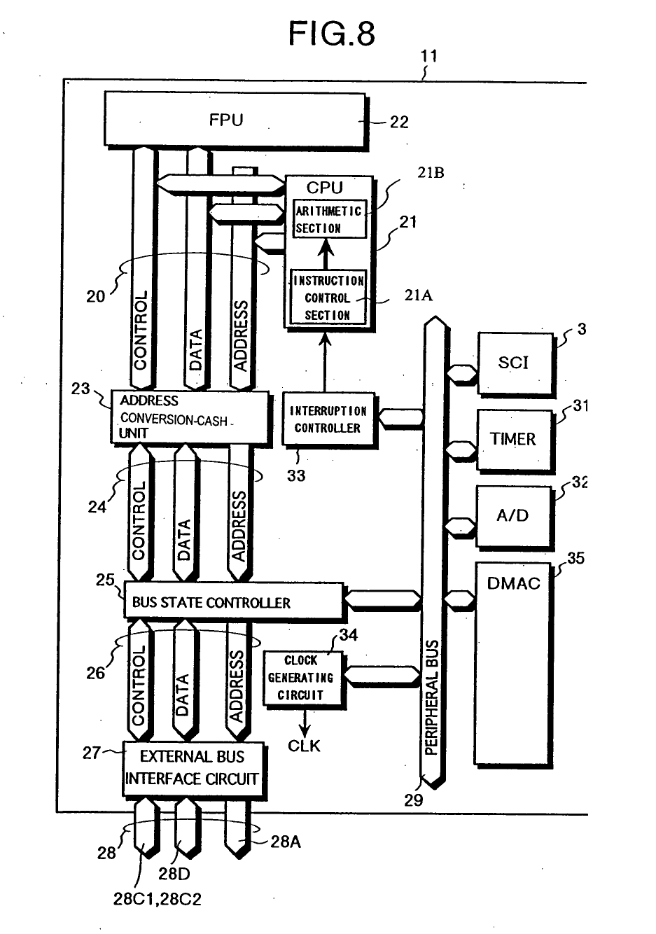

SH7750 sold from HITACHI SEISAKUSHO can be utilized in the data processor chip 11. As illustrated in FIG. 8, the data processor chip 11 has a central processing unit (CPU) 21 and a floating point arithmetic unit (FPU) 22 in a system bus 20. The system bus 20 can be interfaced to a cash bus 24 through an address conversion-cash unit 23. The CPU 21 has an instruction control section 21A for decoding fetched instructions and generating a control signal, and an arithmetic section 21B for performing an integer arithmetic operation by control of the instruction control section 21A. If the fetched instructions are FPU instructions, the CPU 21 performs necessary bus access control such that the FPU 22 can fetch operands or store arithmetic results. The FPU 22 decodes the FPU instructions, and performs a floating point arithmetic operation. The address conversion-cash unit 23 has an address converting mechanism for converting a logic address to a physical address, and also has a data cash memory and an instruction cash memory. In the case of a cash hit, the address conversion-cash unit 23 outputs information relative to the hit to the system bus 20, and writes information of the system bus 20 to the cash memory. In the case of a cash miss hit, the address conversion-cash unit 23 commands an external bus access to a bus state controller 25 so that information relative to the miss hit can be read or written.

The cash bus 24 is connected to the bus state controller 25. The bus state controller 25 gets access to the exterior through an internal bus 26, an external bus interface circuit 27 and a module internal bus 28, or gets access to a peripheral circuit such as SCI (serial communication interface) 30, timer 31 and A/D 32 through a peripheral bus 29 in accordance with commands from the cash bus 24. An interruption controller 33, a clock generating circuit 34, DMAC (direct memory access controller) 35 are connected to the peripheral bus 29. The DMAC 35 can get access to the exterior through the bus state controller 25 in accordance with initialization using the CPU 21. The data processor chip 11 is operated in synchronization with a clock signal CLK as an operating reference clock signal.

In FIG. 6, for example, a data input/output buffer 40, an address output buffer 41, a control signal output buffer 42 and the above logic gate chip 14 are inserted as a buffer circuit into the data bus 28D, the address bus 28A and the control bus 28C1 of the module internal bus 28. The data input/output buffer 40 is constructed by the above buffer chips 13a, 13b. The address output buffer 41 is constructed by the above buffer chips 13c, 13d. The control signal output buffer 42 is constructed by the above buffer chip 13e. The above data input/output buffer 40 interrupts an input in accesses of the memory chips 12a to 12d using the data processor chip 11.

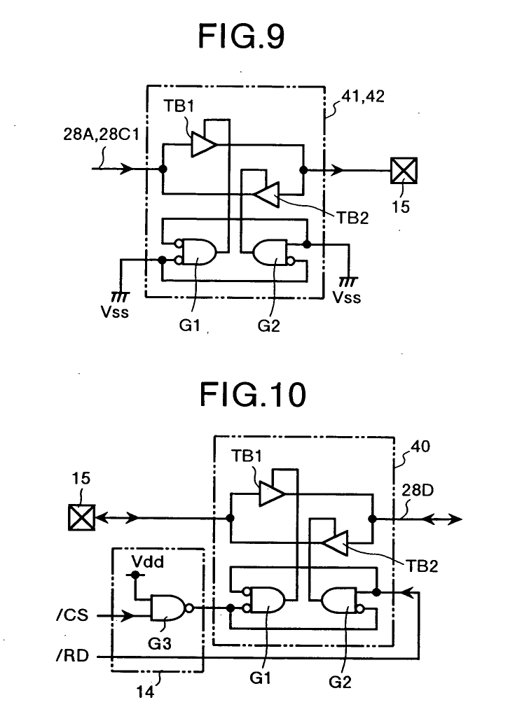

FIG. 9 illustrates the construction of one bit of each of the address output buffer 41 and the control signal output buffer 42. In this construction, tristate buffers TB1, TB2 are connected in reverse parallel with each other. One tristate buffer TB1 is activated and controlled by the output of an AND gate G1, and the other tristate buffer TB2 is activated and controlled by the output of an AND gate G2. Namely, the buffers 41 and 42 can be considered as a tristate type bus switch. Two inputs of the AND gate G1 are fixedly set to a high level, and the tristate buffer TB1 can be set to perform an output operation at any time if operating power is applied to this tristate buffer TB1. The other AND gate G2 is fixedly set to a low output level so that the tristate buffer TB2 is fixedly set to a high output impedance state. Thus, after the operating power is applied, an output buffer able to perform the output operation at any time is realized.

FIG. 10 illustrates the construction of one bit of the data input/output buffer 40. In this construction, tristate buffers TB1, TB2 are connected in reverse parallel with each other. One tristate buffer TB1 is activated and controlled by the output of an AND gate G1. The other tristate buffer TB2 is activated and controlled by the output of an AND gate G2. Namely, the buffer 40 can be considered as a pair of bus switches having cross-connected input and output. The above logic gate chip 14 has a NAND gate G3 having a power voltage Vdd and a chip select signal /CS as two inputs. An output inversion signal of the NAND gate G3 is inputted to the input of one of the AND gates G1, G2. An inversion signal and a non-inversion signal of the above read signal /RD are inputted to the input of the other of the AND gates G1, G2.

A chip select operation of the memory chips 12a to 12d using the data processor chip 11 is commanded by a low level of the signal /CS. In this state, the output of the NAND gate G3 is set to a high level, and the outputs of both the AND gates G1, G2 are set to low levels in response to this high level so that the data input/output buffer 40 is set to a high impedance state. In a chip nonselect state (/CS=high level) of the memory chips 12a to 12d, the output of the AND gate G1 is set to a high level in response to the commands of a reading operation using the signal /RD, and the tristate buffer TB1 can input data from the exterior to the data bus 28D. When no reading operation using the signal /RD is commanded in the chip nonselect state (/CS=high level) of the memory chips 12a to 12d, the output of the AND gate G2 is set to a high level, and the tristate buffer TB2 can output data from the data bus 28D to the exterior. Since the buffer circuits shown in FIGS. 9 and 10 are constructed by utilizing a general purpose buffer circuit HD74LVHC16245, these buffer circuits are approximately set to the same circuit construction. If no general purpose buffer circuit is used, it is not necessary to set the buffer circuits to the same circuit construction.

For example, when the data processor chip 11 and the memory chips 12a to 12d are operated at a high speed of 100 MHz or more, a noise tends to be mixed into the module internal bus 28. A recent semiconductor integrated circuit able to perform a high speed operation tends to have a low power voltage. This is because a time taken to change signals is reduced and the high speed operation can be performed by reducing and restraining consumed power and reducing signal amplitude. However, when the signal amplitude is reduced, a problem exists in that the semiconductor integrated circuit is easily influenced by an external noise. With respect to such a high frequency noise, as mentioned above, the multichip module of a multilayer wiring structure having excellent noise resisting characteristics is firstly formed by selecting a high speed operating device such as the data processor chip 11 and the memory chips 12a to 12d. Secondly, the layout of a chip and an external connecting terminal 15 for strengthening noise resisting performance is adopted with respect to the multichip module. Thus, the above buffer circuits 40, 41, 42, 14 are inserted into the module internal buses 28D, 28A, 28C1. The buffer circuits 40, 41, 42, 14 restrain noises from entering the module internal bus from the wiring substrate 2 with respect to the above first and second noise resisting characteristics strengthening measures about the multichip module 3 itself so as to take the perfect noise measure.

Operations of the buffer circuits 40, 41, 42, 14 in the above viewpoint will be explained. As can be seen from the above description, since the address output buffer 41 for outputting an address signal toward the external connecting electrode 15 and the control signal output buffer 42 for outputting an access control signal toward the external connecting electrode 15 restrain signal inputs at any time, no high frequency noise is flowed-in through these output buffers from the external connecting electrode 15. Further, the data input/output buffer 40 set to a high impedance state in accordance with an operating selection of the memory chips also makes the external noise difficult to flow into the memory chips from the external connecting electrode 15 through the module internal bus. Accordingly, it is possible to strengthen a function for restraining memory data from being broken by the high frequency noise during the memory access operation. Further, control is simplified since it is sufficient to perform a control operation to the high impedance state in response to the operating selection of the memory chips.

Thus, it is possible to strengthen the prevention of the breakdown of the memory data due to the high frequency noise during the memory access operation.

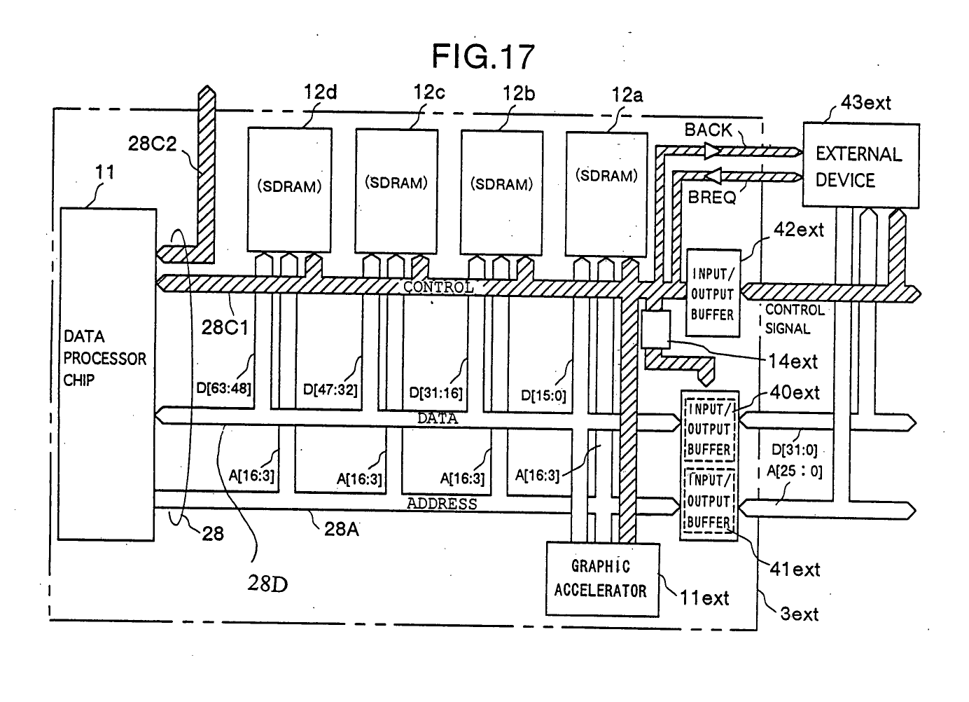

FIG. 17 illustrates a separate functional block diagram of the multichip module. The interior of a multichip module 3ext shown in this figure can be accessed by an external device (e.g., a car navigation system such as a device for reading map data from a CD-ROM, and a device for extracting data of a character broadcast) 43ext as a bus master arranged outside the multichip module 3ext with respect to the multichip module 3 of FIG. 6. For example, the multichip module 3ext includes a graphic accelerator 11ext. Further, a data input/output buffer 40ext, an address input/output buffer 41ext, a control signal input/output buffer 42ext and the above logic gate chip 14ext are inserted as a buffer circuit into the data bus 28D, the address bus 28A and the control bus 28C1 of the module internal bus 28. The data processor chip 11 has a bus adjusting circuit, and the external device 43ext requires a bus right by supplying a bus request signal BREQ to the data processor chip 11. Acknowledge of the bus right with respect to the external device 43ext is returned to the external device 43ext by a bus acknowledge signal BACK. The bus request signal BREQ and the bus acknowledge signal BACK are shown in FIG. 17 such that these signals are inputted and outputted via the control bus 28C1. However, it should be understood that these signals are really inputted and outputted through the bus 28C2.

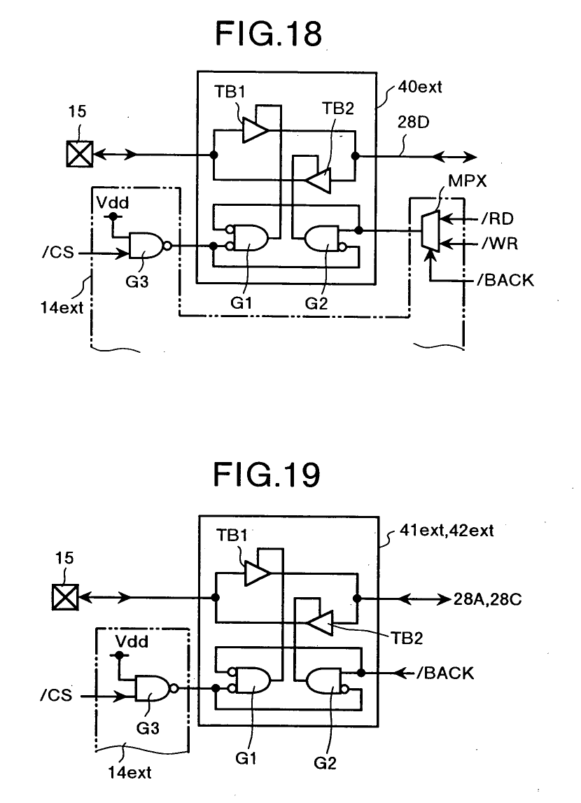

FIG. 18 partially illustrates the input/output buffer 40ext and the logic gate chip 14ext for controlling an operation of this input/output buffer 40ext. FIG. 19 partially illustrates the input/output buffers 41ext, 42ext and the logic gate chip 14ext for controlling operations of these input/output buffers 41ext, 42ext. Circuit elements having the same functions as FIGS. 9 and 10 are designated by the same reference numerals, and their detailed explanations are omitted here.

In the input/output buffers 40ext, 41ext, 42ext, the above chip select signal /CS is supplied to the NAND gate G3, and similar to FIG. 10, an input is interrupted in accesses of the memory chips 12a to 12d using the data-processor chip 11.

As shown in FIG. 19, the input/output buffers 41ext, 42ext function as an output buffer by non-activating the tristate buffer TB2 when the data processor chip 11 acquires the bus right.

In the data input/output buffer 40ext, data directions in reading and writing operations become opposite according to whether the data processor chip 11 or the external device 43ext acquires the bus right. A multiplexer MPX is arranged to support this as illustrated in FIG. 18. When a bus acknowledge signal /BACK is set to a negating state (the data processor chip 11 possesses the bus right), the multiplexer MPX selects a read signal /RD outputted from the data processor chip 11. In contrast to this, when the bus acknowledge signal /BACK is set to an asserting state (the external device 43ext possesses the bus right), the multiplexer MPX selects a write signal /WR outputted from the external device 43ext.

In the examples of FIGS. 18 and 19, the external device 43ext can get access to the graphic accelerator 11ext. However, no external device 43ext can get access to the SDRAMs 12a to 12d by asserting the above chip select signal /CS. This is because the input/output buffers 40ext, 41ext, 42ext are set to the high impedance state by asserting the chip select signal /CS. The NAND gate G3 in FIGS. 18 and 19 is replaced with a two-input NOR gate and the chip select signal /CS is inputted to one input of the two-input NOR gate and an inversion signal of the bus acknowledge signal /BACK is inputted to the other input such that the external device 43ext acquiring the bus right can get access to the SDRAMs 12a to 12d by asserting the chip select signal /CS although this construction is not particularly illustrated.

In the construction of FIG. 17, similar to FIG. 6, the multichip module using the multilayer wiring structure is formed with respect to the high frequency noise, and the layout of a chip and an external connecting terminal 15 for strengthening noise resisting performance with respect to the. multichip module is adopted. Then, the above buffer circuits 40ext, 41ext, 42ext, 14ext are inserted into the module internal buses 28D, 28A, 28C1. The buffer circuits 40ext, 41ext, 42ext, 14 restrain the noise from being mixed into the module internal bus from a side of the wiring substrate 2 with respect to the above first and second noise resisting characteristics strengthening measures about the multichip module 3ext itself so that the noise measures are further perfectly taken. Accordingly, since the buffer circuits 40ext, 41ext, 42ext are set to the high impedance state in accordance with the operating selection of the memory chips, it is possible to strengthen a function for restraining memory data from being broken by the high frequency noise during the memory access operation.

<<Address Delay Measure>>

As explained on the basis of FIG. 3, when a device mounting area of the multichip module is separated into high and low speed operating areas, it is possible to consider that parallel address input timings to the memory chips 12a to 12d are aligned with each other.

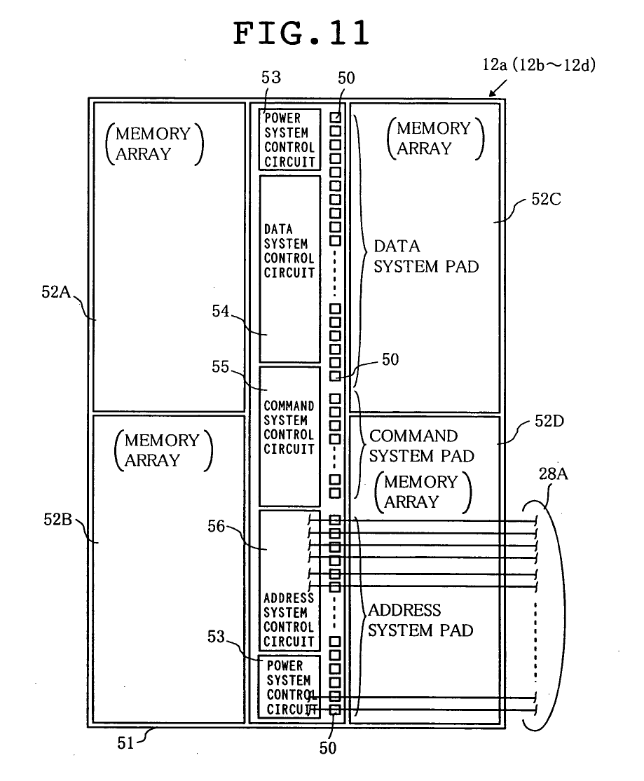

For example, as illustrated in FIG. 11, when bonding pads 50 of the memory chips 12a to 12d are arranged in one line along a longitudinal direction approximately in a central portion of a chip 51, a signal line A[16:3] of the address bus 28A is extended in a direction crossing an arranging direction of the bonding pads 50 and is sequentially joined to the bonding pads 50 of an address system. In FIG. 11, reference numerals 52A to 52D designate memory arrays constituting plural memory banks. Reference numerals 53, 54, 55 and 56 respectively designate a power system control circuit, a data system control circuit, a command system control circuit and an address system control circuit. The signal line A[16:3] shows 14 address lines A16 to A3 in total.

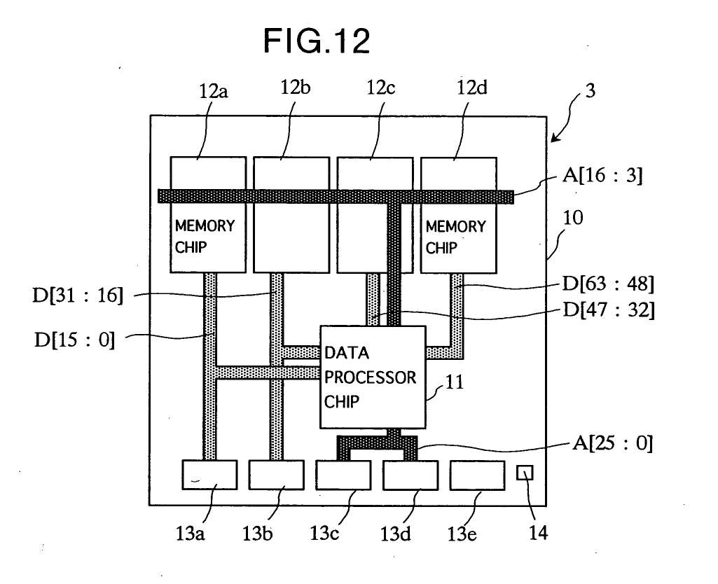

In FIG. 12, a connecting state of the memory chips 12a to 12d and the signal line A[16:3] of the address bus 28A is entirely shown in the multichip module 3. In this figure, the illustration of control buses 28C1, 28C2 is omitted.

In accordance with the layout construction of the address signal line with respect to the address system bonding pads arranged in one line in the above center pad form, the address signal transmitted in parallel with the address bus 28A reaches the address system bonding pads in the same timing with respect to respective parallel bits every memory chips 12a to 12d. Accordingly, it is optimal for the arrangement of the memory chips 12a to 12d such as SDRAMs to be operated at high speed.

In the construction shown in FIG. 12, the data processor chip 11 is connected to the memory chip 12a through 16 data lines D[15:0], and is connected to the memory chip 12b through 16 data lines D[31:16], and is connected to the memory chip 12c through 16 data lines D[47:32], and is connected to the memory chip 12d through 16 data lines D[63:48]. The data lines D[31:16] and [15:0] are connected to buffer circuits 13a and 13b. In contrast to this, 26 address lines A[25:0] are connected to buffer circuits 13c and 13d.

<<Multilayer Wiring Structure>>

FIG. 13 shows one example of the multilayer wiring structure in the above multilayer wiring substrate.

The multilayer wiring substrate 10 has a structure in which buildup layers 61, 62 are formed by respectively overlapping wiring layers of the same layer number on the front and rear faces of a core layer or a base layer 60 having plural wiring layers. It is possible to preferably prevent the module substrate 3 from being thermally warped by front and rear symmetry obtained by forming the buildup layers 61, 62 having an equal layer number on the front and rear faces of the core layer 60.

The core layer 60 is constructed by laminating wiring layers 60A to 60D constructed by copper of four layers through e.g., glass epoxy resin. One buildup layer 61 is constructed by further laminating wiring layers 61A to 61C constructed by copper of three layers through epoxy resin on an upper face of the core layer 60. The other buildup layer 62 is similarly constructed by further laminating wiring layers 62A to 62C constructed by copper of three layers through epoxy resin on a bottom face of the core layer 60. The above wiring layers are suitably connected to each other by through holes, etc. to adopt a mutual necessary connection.

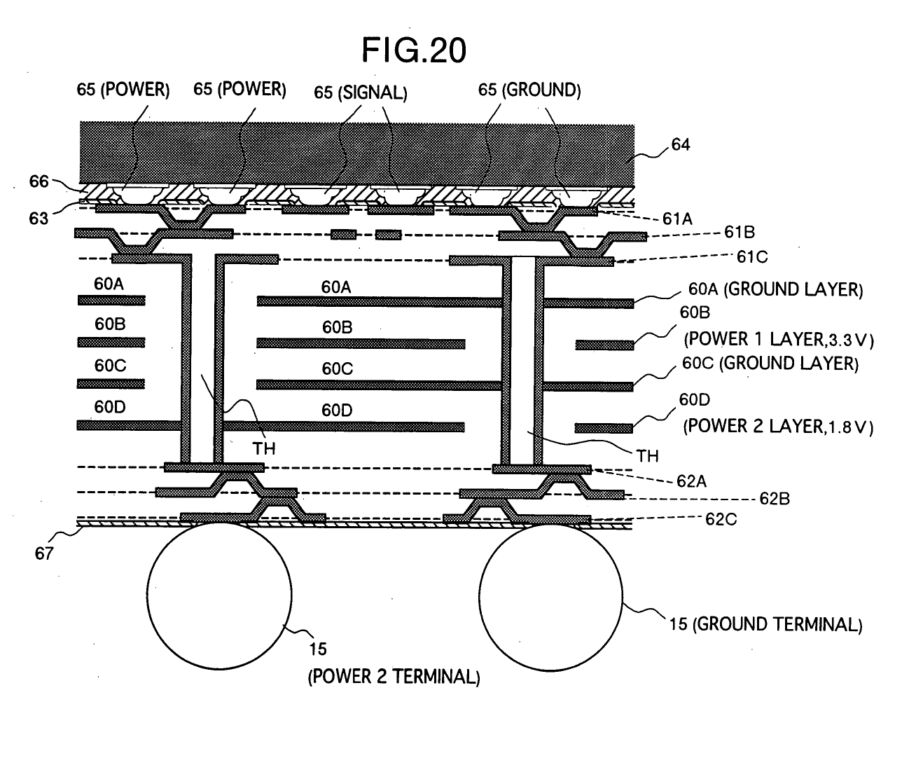

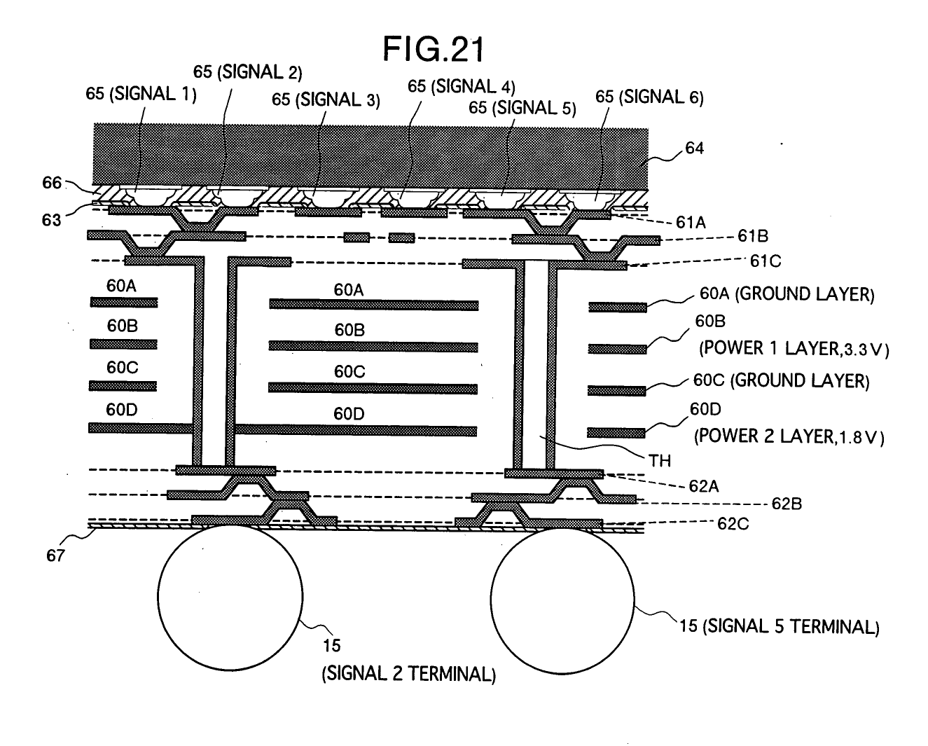

The predetermined wiring layers 60A to 60D are particularly set to a power wiring pattern and a ground wiring pattern formed by a solid pattern uniformly set to a conductive layer on an entire face except for through hole portions selectively formed. It is considered that the equivalent electrostatic capacity between the signal pattern and the power pattern or the ground pattern is increased and can be uniformly set over the entire circuit. The detailed contents of this construction will be explained later by using FIGS. 20 and 21.

An uppermost layer of the buildup layer 61 is covered with an insulating layer (or a protecting layer) 63 such as a solder resist layer except for a portion, of a mounting pad utilized to mount a semiconductor integrated circuit chip 64 such as the data processor chip 11. A bump electrode 65 of the semiconductor integrated circuit chip 64 constructed by gold (Au) is electroconductively connected to the mounting pad through an anisotropic electroconductive film 66 described later, and is fixed to the surface of the buildup layer 61 through the anisotropic electroconductive film 66.

The surface of the buildup layer 62 is covered with an insulating layer 67 such as a resist layer except for a portion forming the external connecting electrode 15. The external connecting electrode 15 is formed by a solder ball in a portion of the wiring layer 62C exposed from the resist layer 67.

The buildup layers 61 and 62 are formed by attaching epoxy resin to the core layer 60 and forming through holes in predetermined desirable portions and repeating a process for forming a wiring pattern constructed by copper on upper faces of the predetermined desirable portions. The buildup layers are formed as follows when a further detailed explanation is made. First, the core layer 60 is dipped into an epoxy resin solution, and epoxy resin layers as first layers are formed on front and rear faces of the core layer 60. Etching is then performed by using a suitable etching mask to form through holes in the epoxy resin layers in portions corresponding to wiring connecting portions. Thereafter, a metallic film constructed by copper and constituting the wiring layer 61C or 62C is formed and etched so that the wiring layer 61C or 62C is formed. The wiring layer 61A or 62A is formed by sequentially performing the above processes. Thereafter, the buildup layers 61 and 62 are formed by selectively forming insulating films 63 and 67 such as solder resist films.

In a substrate forming the buildup layer on one face thereof, characteristics of the core layer and the buildup layer with respect to heat are different from each other. Therefore, there is a fear that the multichip module is warped by an influence such as thermal stress generated at a mounting time of the multichip module. Therefore, there is a case in which any one of the layers within the substrate or the core layer and the buildup layer are separated from each other, and internal wiring is disconnected. As explained in FIG. 13, the influence of the thermal stress can be reduced and restrained since the characteristics with respect to heat on both the front and rear faces of the core layer 60 are equal to each other in the substrate in which the buildup layers 61, 62 are formed on both the faces of the core layer 60. Accordingly, the possibility of interlayer separation and destruction of the wiring can be reduced so that a reliable multichip module can be realized.

The thickness of the multilayer wiring substrate 10 as a total of thicknesses of the core layer 60 and the respective buildup layers 61 and 62 is not particularly limited, but is set to 1.22 mm. Further, the distance between the rear face of a thickest chip among the data processor chip 11, the memory chips 12a to 12d, the buffer chips 13a to 13d and the logic gate chip 14 arranged on one surface of the multilayer wiring substrate 10, and each external connecting electrode 15 formed on the other surface of the multilayer wiring substrate 10, i.e., height of the multichip module 3 is set to 2.3 mm. As a result, the mounting height of the multichip module 3 is set to 2.7 mm or less.

Thus, the multichip module 3 can be easily mounted to a mounting substrate arranged within an electronic device requiring each element such as compactness, thickness and light in weight as in a portable telephone, a hand held computer, etc.

There is also the following power connecting mode although this mode is not shown in FIG. 13. For example, as shown in FIG. 13, there is also a case in which a power terminal or a ground terminal arranged in a semiconductor chip 11 cannot be linearly connected to a connecting terminal 15 (ground terminal) or a connecting terminal 15 (power 1 terminal) through a through hole. In this case, the connection is once made from the power terminal or the ground terminal arranged in the semiconductor chip 11 to a wiring layer 60A (ground layer) or 60D (ground layer) formed within the core layer 60, or is once made from the power terminal or the ground terminal to a wiring layer 60B (power 1 layer) or a wiring layer 60C (power 2 layer). Thereafter, the connection is linearly made from the wiring layers 60A (ground layer), 60D (ground layer), the wiring layer 60B (power 1 layer) and the wiring layer 60C (power 2 layer) corresponding to connectable portions of the corresponding connecting terminal 15 (ground terminal), connecting terminal 15 (power 1 terminal) or connecting terminal 15 (power 2 terminal) of the multichip module substrate 10 to the connecting terminal 15 (ground terminal), the connecting terminal 15 (power 1 terminal) or the connecting terminal 15 (power 2 terminal).

FIG. 20 is a view for explaining FIG. 13 in further detail, and shows the connection relation of a gold bump electrode 65 such as the ground terminal (GND) or the power terminal (VDD, 3.3 V, 1.8 V) arranged in the semiconductor integrated circuit chip 64, and each external connecting electrode 15 formed in the multilayer wiring substrate 10.

As shown in this figure, a terminal 65 arranged in the semiconductor integrated circuit chip 64 and receiving the supply of a ground electric potential is connected to a solder bump electrode 15 as the ground terminal for receiving the supply of the ground electric potential (0 V) through wirings 61A, 61B, 61C arranged in the buildup layer 61 and wirings 62A, 62B, 62C arranged in the buildup layer 62. The wiring layer 61C is electrically connected to the wiring layers 60A and 60C in a portion of a through hole TH formed in the core layer 60 so that the wiring layers 60A and 60C are set to ground layers for receiving the supply of the ground electric potential.

On the other hand, a terminal 65 arranged in the semiconductor integrated circuit chip 64 and receiving the supply of a power electric potential (1.8 V) is connected to a solder bump electrode 15 as a power 2 terminal for receiving the supply of the power electric potential (1.8 V) through the wirings 61A, 61B, 61C arranged in the buildup layer 61 and the wirings 62A, 62B, 62C arranged in the buildup layer 62. The wiring layer 61C is electrically connected to the wiring layer 60D in a portion of the through hole TH formed in the core layer 60 so that the wiring layer 60D is set to a power 2 layer for receiving the supply of the power electric potential (1.8 V).

A terminal 65 arranged in the semiconductor integrated circuit chip 64 and receiving the supply of the power electric potential (3.3 V) is connected to a solder bump electrode 15 as a power 1 terminal for receiving the supply of the power electric potential (3.3 V) through the wirings 61A, 61B, 61C arranged in the buildup layer 61 and the wirings 62A, 62B, 62C arranged in the buildup layer 62 although this construction is not shown in FIG. 20. The wiring layer 61C is electrically connected to the wiring layer 60B in a portion of the through hole TH formed in the core layer 60 so that the wiring layer 60B is set to a power 1 layer for receiving the supply of the power electric potential (1.8 V).

Thus, the wiring layers 60A to 60D formed within the core layer 60A are coupled to the power electric potential (3.3 V, 1.8 V) or the ground electric potential so that the effect of reducing noises is generated as mentioned above.

FIG. 21 is a view for explaining FIG. 13 in further detail, and shows the connection relation of the gold bump electrode 65 as a signal terminal arranged in the semiconductor integrated circuit chip 64 and each external connecting electrode 15 formed in the multilayer wiring substrate 10.

As shown in this figure, a terminal 65 (signal 2) or 65 (signal 5) arranged in the semiconductor integrated circuit chip 64 and receiving the supply of a signal 2 is connected to a solder bump electrode 15 (signal 2) as a signal terminal for receiving the supply of the signal 2 through wirings 61A, 61B, 61C arranged in the buildup layer 61 and wirings 62A, 62B, 62C arranged in the buildup layer 62. The wiring layer 61C or 62A is not electrically connected to the wiring layers 60A to 60D in a portion of the through hole TH formed in the core layer 60, and the wiring layers 61C to 62A are electrically connected in a portion of the through hole TH. The bump 65 for receiving the supply of respective signals 1, 3, 4 and 6 is similarly electrically connected to the predetermined desirable bump electrode 15 in an unillustrated portion.

<<Assembly of Multichip Module>>

A method for assembling the multichip module 3 in a flip chip system will be explained.

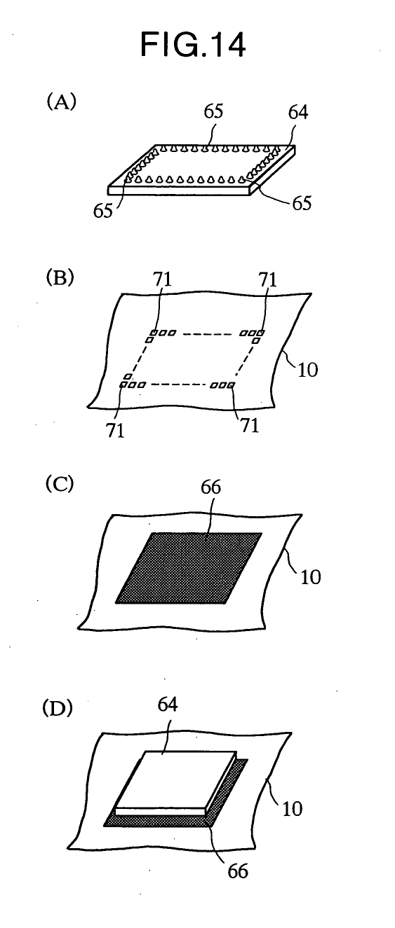

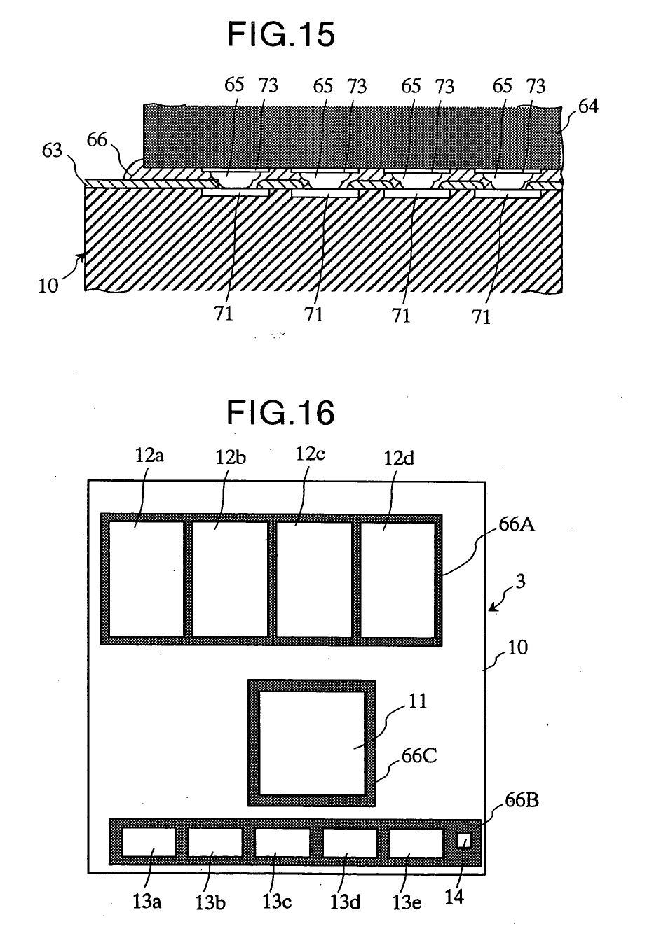

FIG. 14 shows some main portions in a process for mounting a bare chip to a module substrate in the flip chip system. FIG. 15 illustrates a sectional structure of a joining portion of the bump electrode 65 and a mounting pad 71.

FIG. 14A typically illustrates the semiconductor integrated circuit chip 64 as one bare chip. Reference numeral 65 designates a bump electrode. The bump electrode 65 is formed in a bonding pad 73 (see FIG. 15) of the semiconductor integrated circuit chip 64, and the surface of the bump electrode 65 is plated with e.g., gold.

As shown in FIG. 14B, the above mounting pad 71 arranging the bump electrode 65 thereon and electroconductively connected to the bump electrode 65 is exposed to the surface of the module substrate 10. For example, the surface of the mounting pad is plated with gold.

As shown in FIG. 14C, an anisotropic electroconductive film 66 is stuck to the surface of the mounting pad 71. The anisotropic electroconductive film 66 is a thermosetting resin film in which electroconductive particulates such as nickel particles are dispersed and mixed into thermosetting resin. When force is applied to this anisotropic electroconductive film 66 in its thickness direction, the anisotropic electroconductive film 66 is elastically deformed as illustrated in FIG. 15, and the electroconductive particulates included in this deforming portion are chained and come in contact with each other so that electroconductivity is obtained only in this portion. This state is maintained by hardening the electroconductive particulates by heat and an adhesive action is also shown by this thermosetting property. The size of the anisotropic electroconductive film 43 stuck to the substrate may be determined in conformity with the size of a connected IC chip.

Finally, as shown in FIG. 14D, the bump electrode 65 of the semiconductor integrated circuit chip 64 as a bare chip is crimped onto the anisotropic electroconductive film 66 so as to be joined to the predetermined mounting pad 71 on the module substrate 10. Thereafter, the anisotropic electroconductive film 66 is hardened by applying heat so that the semiconductor integrated circuit chip 64 is stuck and electroconductive connection of the bump electrode 65 and the mounting pad 71 is completed as shown by a sectional structure of FIG. 15.

When the multichip module 3 illustrated in FIG. 3 is assembled, processing for sticking the separate anisotropic electroconductive film 66 one by one every one bare chip and crimping and thermosetting the bare chip on this film must be repeated 11 times if 11 bare chips in total constructed by the data processor chip 11, the memory chips 12a to 12d, the buffer chips 13a to 13e and the logic gate chip 14 are mounted to the module substrate 10 one by one as explained in FIG. 14. Accordingly, working efficiency is extremely low.

Therefore, in view of a reduction in assembly process number, mounting pads are grouped and arranged in the module substrate 10 such that semiconductor integrated circuit chips approximately having an equal height size, e.g., semiconductor integrated circuit chips of the same kind are arranged in one line and can be mounted every group of the semiconductor integrated circuit chips. The anisotropic electroconductive film is then stuck every grouped mounting pad, and a mounting pattern and the bump electrode of the semiconductor integrated circuit chip are electroconductively connected to each other through the stuck anisotropic electroconductive film. For example, in the case of the multichip module 3 arranging the bare chip therein as shown in FIG. 3, as illustrated in FIG. 16, an array of the memory chips 12a to 12d is set to one group and one anisotropic electroconductive film 66A is stuck. An array of the buffer chips 13a to 13e and the logic gate chip 14 is set to one group and one anisotropic electroconductive film 66B is stuck, and one anisotropic electroconductive film 66C is independently stuck for the data processor chip 11. Then, the bare chip is crimped onto the anisotropic electroconductive film such that the bump electrode 65 of the corresponding bare chip is joined to the corresponding mounting pad 71 every group. Heat is collectively applied so that the anisotropic electroconductive films are hardened. Accordingly, a sticking time number of the anisotropic electroconductive films 66A, 66B, 66C, a crimping time number or a crimping-heating time number of the bare chip with respect to the anisotropic electroconductive films 66A, 66B, 66C can be respectively reduced to about three times. Accordingly, the assembly process number of the multichip module 3 can be reduced. Simplification of the assembly process contributes to the improvement of yield and reliability of the multichip module. Further, manufacture cost of the multichip module can be reduced.

In the above description, the invention made by the present inventors is concretely explained on the basis of the embodiments. However, the present invention is not limited to these embodiments, but can be variously modified in the scope not departed from the features of the invention.

For example, the semiconductor integrated circuit chip mounted to the multichip module is not limited to the bare chip, but may be also a chip sealed by a compact or thin package such as CSP (chip size package). Further, the use of the memory chip is not limited to a main memory and a cash memory, but may be set to a use accessed by the data processor. Further, an accelerator as an arithmetic processor for reducing a processing burden of the data processor, e.g., a circuit chip for graphics processing, error correction processing, compression processing, etc. may be also mounted together to the multichip module. Further, the number of memory chips mounted to the module substrate, the number of buffer chips, the number of data processors, etc. are not limited to the above explanation.

The present invention can be widely applied to an image processor, a voice processor and a multimedia device for taking a high speed data treatment such as image processing, and a portable information terminal or a portable communication terminal for performing communication and image display, etc.

1. A semiconductor device comprising:
a wiring substrate having a plurality of terminals
a semiconductor device providing data signals, address signals, control signals and clock signal to outside; and
a plurality of memory devices receiving said data signals, said address signals and control signals from said semiconductor device and operating in response to said clock signal provide from said semiconductor device,
wherein said semiconductor device comprising:
a semiconductor chip; and
a plurality of external terminals electrically connecting with said semi-conductor chip,
wherein said memory device comprising:
a memory chip; and
a plurality of external terminals electrically connecting with said memory chip,
wherein said wiring substrate having a plurality of layers including a ground layer,
wherein said ground layer electrically couples to a first external terminal of semiconductor chip and a first external terminal of memory device, and
wherein said semiconductor device and said memory devices are mounting over said wiring substrate.

2. The semiconductor device according to claim 1,
wherein said semiconductor device is supplied with a first operational potential, and
wherein said memory device is supplied with a second operational potential higher than said first operational potential.

3. The semiconductor device according to claim 1,
wherein said wiring substrate having a first power source layer which electrically couples to a second external terminal of said semiconductor device to supply a first potential, and
wherein said wiring substrate having a second power source layer which electrically couples to a second external terminal of said memory device to supply a second potential higher than said first potential.

4. The semiconductor device according to claim 3, wherein said first power source layer and said second power source layer are arranged in a different area of a layer of said wiring substrate.

5. A semiconductor device comprising:
a wiring substrate having a plurality of terminal and a plurality of layers including a ground layer;
a semiconductor device outputting address signals, control signals, and a clock signal and supplied with a first operational voltage; and
a plurality of memory devices receiving said address signals and control signals and operating output of data signals in response to said clock signal and supplied with a second operational voltage higher than said first operational voltage,
wherein a first external terminals of said semiconductor device and a first external terminals of said memory device are electrically coupled to said ground layer via a through-hole,
wherein said semiconductor device and said memory devices are mounting over said wiring substrate, and
wherein said semiconductor device, said memory device and said wiring substrate are included in a sealing member.

6. The semiconductor device according to claim 5,
wherein said wiring substrate has a first voltage layer which is electrically coupled to a second external terminal of said semiconductor device to supply said first voltage, and
wherein said wiring substrate has a second voltage layer which is electrically coupled to a second external terminal of said memory device to supply said second voltage.
